(19) United States
(12) Patent Application Publication
(10) Pub. No.: US 2006/0205181 A1
(43) Pub. Date: Sep. 14, 2006

(54) Method for forming an optical silicon layer on a support and use of said method in the production of optical components

(75) Inventors: Emmanuel Hadji, Fontaine (FR); Jean-Louis Pautrat, Grenoble (FR)

Correspondence Address: PEARNE & GORDON LLP, 1801 EAST 9TH STREET, SUITE 1200, CLEVELAND, OH, 44114-3108, US

(73) Assignee: Commissariat A L'Energie Atomique, Paris (FR)

(21) Appl. No.: 11/411,537

(22) Filed: Apr. 26, 2006

Related U.S. Application Data
(63) Continuation of application No. 10/800,450, filed on Mar. 15, 2004, now abandoned.
Application No. 10/800,450 is a continuation of application No. 09/673,005, filed on Nov. 27, 2000, now abandoned.

(30) Foreign Application Priority Data
Feb. 7, 2000 (WO) PCT/FR00/00278
Feb. 10, 1999 (FR) 99 01559

(51) Int. Cl. H01L 21/30

(52) U.S. Cl. 438/458

(57) ABSTRACT

The invention relates to a process for the formation of a silicon layer (22a) with a determined thickness on a support (10), for optical purposes. The process comprises the following steps:

a) molecular bonding of a silicon block (20a) on the support, the silicon block having a surface layer (22a) delimited by a cleavage area, b) cleavage of the silicon block along the cleavage area to detach the surface layer from it, c) adjustment of the thickness of the said surface layer. Applications to the manufacture of optical components.

### TECHNICAL FIELD

The invention relates to a process for the formation of a silicon layer for optical purposes on a support, and a number of applications of the process to make optical components.

A silicon layer for optical purposes means a layer in an optical component that contributes to conducting, reflecting, transmission and/or generation of light.

The invention relates particularly to applications for the manufacture of mirrors such as Bragg mirrors and the manufacture of optical emitter micro-cavity cells.

### STATE OF PRIOR ART

Silicon is widely used in the manufacture of microelectronics circuits.

However in the optical field, the indirect prohibited band of silicon confers very weak radiation properties that make it impossible to use silicon as is to emit light.

At the present time, there are no silicon-based light emitter devices on the market.

However, silicon emitters would have some advantages because technologies are highly developed for silicon and are consequently inexpensive.

Furthermore, it would be possible to combine optical components with electronic components and integrate them in microelectronics circuits.

A number of uses of other semiconductors are known, mainly type III-V semiconductors for the manufacture of micro-cavities. Micro-cavities comprise an active medium in the form of a layer with a thickness equal to a multiple of the half-wave length of the working light, and are placed in sandwich form between a first mirror and a second mirror.

Document (1) referenced at the end of this description relates to the manufacture of Fabry-Pérot type amorphous silica-based micro-cavities doped with erbium.

The micro-cavities are delimited by two Bragg mirrors.

The amorphous nature of the materials used for the manufacture of these micro-cavities very significantly reduces light emission capabilities. On the other hand, the incorporation of rare earth ions enables the use of this type of micro-cavity.

Document (2), which is also referenced at the end of the description, describes a process for making a crystalline Bragg mirror. The process consists essentially of growing silicon on a support, and then implanting oxygen, and then forming a buried silicon oxide layer in the silicon. Repetition of these operations creates a Bragg mirror with several periods.

However, this process depends essentially on a technique called SIMOX (Separation by Implantation of Oxygen) that is apparently not used in the microelectronics industry.

### DESCRIPTION OF THE INVENTION

The purpose of this invention is to propose a process for the formation of a silicon layer and particularly a crystalline silicon layer in order to make optical components and particularly micro-cavity light emission sources.

Another purpose is to propose a similar process for making optical components at a particularly low cost.

Another purpose is to propose the said process for applications for making Bragg mirrors and micro-cavity optical emitters.

In order to achieve these purposes, the purpose of the invention is more specifically a process for the formation of a silicon layer for optical purposes with a given (optical) thickness, on a support. According to the invention, the process comprises the following steps in sequence:
a) Molecular bonding of a silicon block on the support on which there may or may not already be other layers, the silicon block having a surface layer delimited by a cleavage area approximately parallel to its surface, and with a thickness greater than (or less than) the said determined thickness, and the silicon block being covered by a silicon oxide layer brought into contact with the support during bonding,
b) Cleavage of the silicon block along the cleavage area to detach the surface layer fixed to the support from it,

c) thinning (or thickening) the said surface layer until a thickness approximately equal to the said determined thickness, is obtained.

Molecular bonding refers to bonding involving a molecular bond between surfaces in contact without the insertion of a binder.

The use of a cleavage technique is well known in the microelectronics field, and for example is described in document (3) referenced at the end of the description. This technique is an efficient way of forming a silicon layer, particularly a layer of crystalline silicon on the surface of a support, and particularly on a support that does not have the same crystalline mesh or the same crystalline structure as silicon.

The process according to the invention is a means of implementing the cleavage process in the optical field despite the limitations mentioned above.

According to one possible use of the process, the thickness of the surface layer in step a) is greater than the determined thickness. In this case, step c) consists of thinning this layer by a mechanical, chemical or mechanical-chemical method.

In particular, the silicon layer may be thinned by polishing or by a treatment combining surface oxidation of the layer and selective elimination of the oxide by etching.

According to a second possibility, a silicon block with a surface layer delimited by the cleavage area can also be used in step a), with a thickness less than the determined thickness. In this case, the thickness of the surface layer can be increased by crystalline growth during step c).

For example, crystalline growth may be based on a process such as vapor phase epitaxy.

Before the bonding step, the silicon block may be prepared by performing hydrogen implantation through one of its faces to form an embrittled area extending approximately along a plane parallel to the said face and forming the cleavage area. The implantation energy is adjusted to form the cleavage area at a depth which is either greater than or less than the determined thickness, depending on the selected implementation method.

In this case the determined thickness means the thickness of the surface layer of silicon necessary to obtain a given optical behavior. For example, it may be a thickness equal to or proportional to

$$\frac{λ}{4 {n}_{s}}$$

where λ is the working wavelength of produced or received light and nₛ is the refraction index of silicon.

According to one preferred embodiment, a silicon oxide layer is formed on the silicon block, and more particularly on the implantation face. This layer is preferably formed before implantation, and then comes into contact with the support during the molecular bonding step in the process according to the invention.

One particular application of the invention relates to a process for manufacturing a Bragg mirror with wavelength λ on a support. According to this process, a stack of layers is formed comprising alternately at least one layer of silicon oxide with optical thickness

$$\frac{λ}{4 {n}_{o}} ,$$

where nₒ denotes the refraction index of the silicon oxide and at least one silicon layer with an optical thickness equal to

$$\frac{λ}{4 {n}_{s}} ,$$

where nₛ is the refraction index of silicon, and the said silicon layer is formed according to the process mentioned above.

For example, the oxide layer could be the oxide layer mentioned above and formed on the silicon block before implantation.

Preferably, the Bragg mirror comprises a plurality of periods, in other words a plurality of silicon layers alternating respectively with several silicon oxide layers.

For example, the silicon oxide layers may be formed by chemical vapor deposition using a Plasma Enhanced Chemical Vapor Deposition (PECVD) process.

Another particular application of the invention is a process for the manufacture of an optical component with a working wavelength λ comprising:
the formation of a Bragg mirror according to the process mentioned above,
formation of a layer of active material on the Bragg mirror by crystalline growth, to form a cavity,
formation of a second mirror on the cavity.

The active material may be made of pure crystalline silicon or it may contain an active element, for example such as erbium or neodymium impurities.

The active material may also be an SiGe, SiGeC or SiC alloy in the form of a thin film, in the form of a quantic boxes structure or multi-layers structure with several films made of different materials.

A quantic boxes structure means a matrix made of a first material containing nanometric inclusions of a second material, the prohibited band width of the second material being narrower than the prohibited band width of the first material. For example, the cavity material(s) may be formed by vapor phase crystalline growth or molecular jet. Their thickness, or at least the thickness of the cavity, is adjusted to correspond to a required optical thickness as a function of a given working wavelength.

The second mirror that covers the cavity may be a simple metallic mirror, or preferably a Bragg mirror obtained according to the process described above.

The process for transferring a silicon layer with a controlled thickness may also be used to make the cavity of an optical emitter.

The manufacture of the optical emitter may comprise:
formation of a first Bragg mirror on a support,
formation of a silicon layer covering a silicon oxide layer on the Bragg mirror, the silicon layer being formed in accordance with the process described above, and,
formation of a second mirror above the silicon layer.

The mirror may be formed directly in contact with the silicon layer or it may be separated from it by other insertion layers.

The silicon oxide layer may be formed on the first Bragg mirror before the silicon layer is transferred to it. But preferably, it can be formed directly on the surface of the silicon layer, in other words on the silicon block, also before the transfer.

As for the previous embodiment, the second mirror may be a traditional mirror; for example a metallic layer or a Bragg mirror obtained according to the process described above.

Other characteristics and advantages of this invention will become clearer from the following description with reference to the Figures in the attached drawings. This description is purely for guidance and is in no way restrictive.

### BRIEF DESCRIPTION OF THE FIGURES

FIG. 1 is a diagrammatic section through a silicon block in which a cleavage area is formed.

FIG. 2 is a diagrammatic section through an assembly obtained by transferring the structure in FIG. 1 onto a support.

FIG. 3 is a diagrammatic section through the assembly shown in FIG. 2 after cleavage along the cleavage area.

FIG. 4 is a diagrammatic section through the assembly in FIG. 3 after a finishing operation.

FIGS. 5 and 6 are diagrammatic sections illustrating the manufacturing steps for an Si/SiO₂ multi-layer structure starting from the assembly in FIG. 4.

FIGS. 7, 8 and 9 are diagrammatic sections illustrating steps in the manufacture of a micro-cavity emitter module starting from a multi-layer structure like that obtained after the step shown in FIG. 6.

FIGS. 10, 11 and 12 are diagrammatic sections illustrating the manufacturing steps for another micro-cavity emitter module.

FIGS. 13, 14 and 15 are diagrammatic sections illustrating the manufacturing steps of yet another micro-cavity emitter module.

### DETAILED DESCRIPTION OF EMBODIMENTS OF THE INVENTION

For simplification reasons, identical, similar or equivalent parts in the Figures described below are given the same references. Furthermore, the given description relates to the manufacture of components, devices or parts of devices with a given working wavelength or central wavelength, denoted λ.

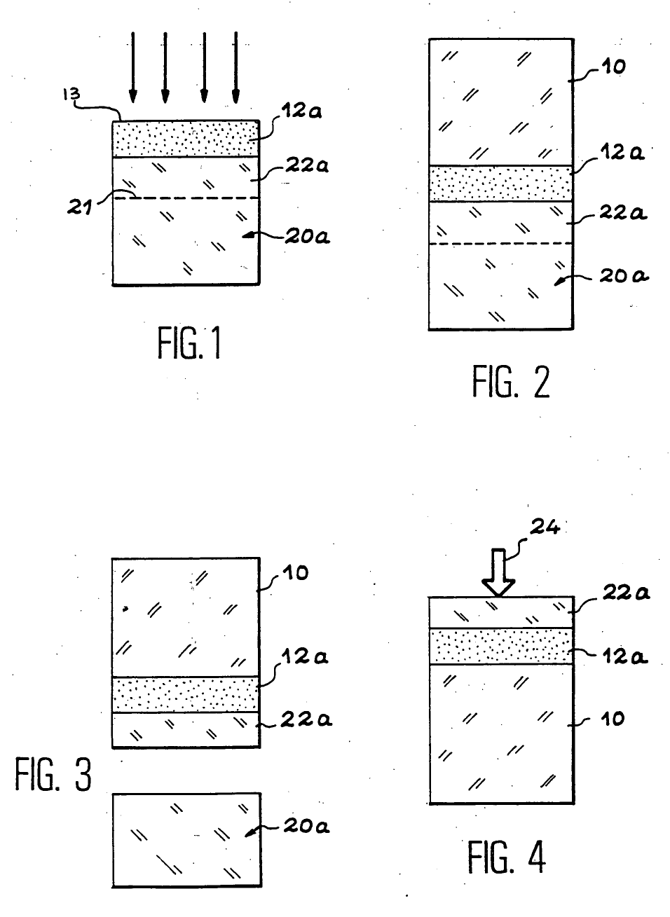

FIG. 1 shows a block of monocrystalline silicon 20a in which hydrogen ions H⁺ are implanted. The implantation is shown diagrammatically in the form of arrows.

The implantation is made with a sufficient dose and energy to form an embrittled area 21 denoted as the cleavage area, at a given depth in the block 20a.

The cleavage area thus delimits a surface layer 22a in the silicon block. The depth of the cleavage area, adjusted with the implantation energy, is chosen to exceed the thickness of a silicon layer that is to be formed for optical purposes.

Thus, if we want to form a

$$\frac{λ}{4 {n}_{s}}$$

thick layer, where nₛ is the refraction index of silicon, the implantation depth and therefore the thickness of the surface layer 22a are chosen to be greater than this value.

FIG. 1 also shows that the surface layer 22a of block 20a is covered by a first layer 12a of silicon oxide. For example, the thickness of the oxide layer may be adjusted to

$$\frac{λ}{4 {n}_{o}} ,$$

where n₀ is the refraction index of silicon oxide. The oxide layer may be formed by chemical vapor deposition, or possibly by thermal oxidation of the silicon in block 20a.

The thickness of the first oxide layer 12a is adjusted, for example by chemical etching or mechanical-chemical etching.

The free surface 13 of the silicon oxide layer 12a visible in FIG. 1 and the free surface of a support (not shown) are then subjected to a treatment to enable their subsequent molecular bonding. For example, the treatment includes chemical cleaning.

The support is formed by a platform 10. This support is in the form of a single piece substrate, or a substrate comprising several layers of different materials.

In the example shown in FIG. 2 described below, the support is a block of silicon, glass or quartz.

Molecular bonding shown in FIG. 2 is obtained by transferring the assembly formed by the silicon block 20a and the oxide layer 12a onto the support 10, in order to bring the free faces of the silicon oxide layer 12a and the platform 10 into contact.

A subsequent operation illustrated in FIG. 3 consists of making a cleavage of the silicon block 20a along the previously implanted cleavage area.

Cleavage may be assisted by heat treatment.

It is observed that after cleavage has terminated, the surface layer 22a remains fixed to the platform 10 through the silicon oxide layer 12a.

The silicon block 20a that is detached from the surface layer may be subjected to another ionic implantation to form a new cleavage area on it. It can then be made using a transfer process like that described.

FIG. 4 shows the assembly consisting of the platform 10, the oxide layer 12a and the surface layer 22a. The assembly is inverted compared with the assembly in FIG. 3. An arrow 24 indicates the treatment applied to adjust the thickness of the surface layer.

In the example described, the initial thickness of the surface layer 22a is greater than the required thickness. Thus, the thickness adjustment treatment consists of thinning the layer. This treatment may be made by polishing or by a series of surface oxidation and selective etching operations to eliminate the oxide formed each time.

According to one variant embodiment of the process, the surface layer may also be initially formed with a thickness less than the required thickness; in this case the cleavage area is implanted in the silicon block at a depth less than

$$\frac{λ}{4 {n}_{s}} .$$

In this case, the step to adjust the thickness in FIG. 4 consists of increasing the thickness of the layer. This may be done by silicon growth on the surface of the surface layer.

The process described above may be iterated to make special optical components or devices. Some examples are given below.

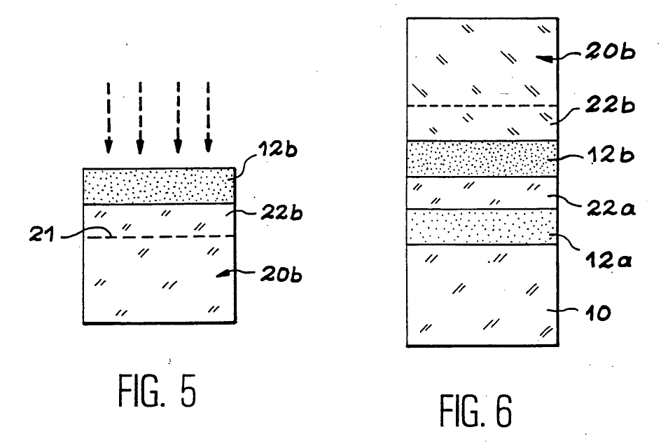

FIG. 5 shows the formation of a new silicon oxide layer 12b on a monocrystalline silicon block 20b. Just like block 20a in FIG. 1, the silicon block 20b has a cleavage area 21 that delimits its surface layer 22b. The cleavage area is formed by the implantation of hydrogen ions.

Furthermore, the process for the formation of the new silicon oxide layer 12b is identical to the process described for the for formation of the first oxide layer 12a.

The thickness of the new oxide layer is also adjusted to a value equal to

$$\frac{λ}{4 {n}_{o}} .$$

FIG. 6 shows the transfer of the new silicon block in FIG. 5 onto the structure in FIG. 4.

The surface of the silicon oxide surface layer 12b covering the silicon block 20b is brought into contact and is glued onto the silicon layer 22a by molecular bonding, the thickness of the silicon layer 22a having been adjusted before this operation.

In this structure, it can be seen that the assembly formed by the platform 10, the first layer of silicon oxide 12a and the first silicon layer 22a is used as a support for the formation of a new set of alternating SiO₂/Si layers.

Another cleavage separates block 20b from its surface layer 22b that remains fixed to the subjacent silicon oxide layer 12b.

An adjustment of the thickness of the surface silicon layer 22b can give a structure like that shown in FIG. 7.

This structure comprises an alternating stack of silicon oxide and oxide layers on the platform 10, the optical thickness of which is adjusted as a function of a given wavelength. This stack, marked as reference 30, forms a Bragg mirror.

Obviously, depending on the required reflection properties, the number of SiO₂/Si alternations in the Bragg mirror may be increased by repeating the steps in the process described above.

FIG. 8 shows a step in the process for manufacturing an optical component comprising the Bragg mirror 30 in the structure in FIG. 7.

The step in FIG. 8 includes the formation of an optical cavity 34 made of an active material on the last surface layer of silicon 22b.

The cavity 34 is made by growth of one or several materials selected from Si, SiGe, SiGeC, SiC. These materials can contain doping impurities such as erbium impurities forming active elements.

The cavity may be in the form of a solid block, in the form of one or more thin layers, or in the form a quantic boxes structure or in the form of a multi-layer structure combining layers of different materials chosen from the materials mentioned above. Its thickness is adjusted as the material grows as a function of the working wavelength λ.

For example, a silicon cavity may comprise a series of very thin silicon layers and SiGe alloy layers. The SiGe layers are of the order of 5 nm thick and do not create any dislocations due to a mismatch of the crystalline mesh, but can form quantic wells.

Similarly, the mismatch in meshes between the silicon layers and the very thin germanium layers may cause the formation of germanium islands that form quantic boxes. These islands considerably increase the capacity of the cavity 34 to emit light.

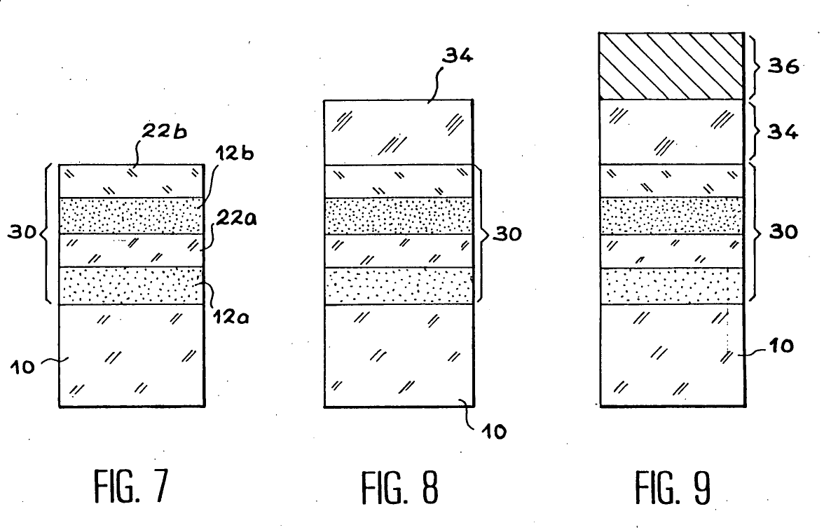

As shown in FIG. 9, the optical component is completed by the installation of a second mirror 36 on the cavity 34.

For example, the second mirror 36 may be a conventional Bragg mirror obtained by successive deposition of SiO₂/Si layers using a Plasma Enhanced Chemical Vapor Deposition (PECVD) process.

The second mirror 36 may also be made using the process described above for making the first Bragg mirror 30.

Finally, the second mirror 36 may also be a conventional metallic mirror obtained by deposition of a metallic film. This type of deposition may be made by evaporation.

FIGS. 10 to 12 also show another possible embodiment of the invention.

FIG. 10 shows a first step that consists of forming a mirror 30 on a silicon platform 10.

The mirror 30 may be a Bragg mirror like that described in the reference to FIG. 7 or a mirror of another type like the mirror 36 in FIG. 9 described above.

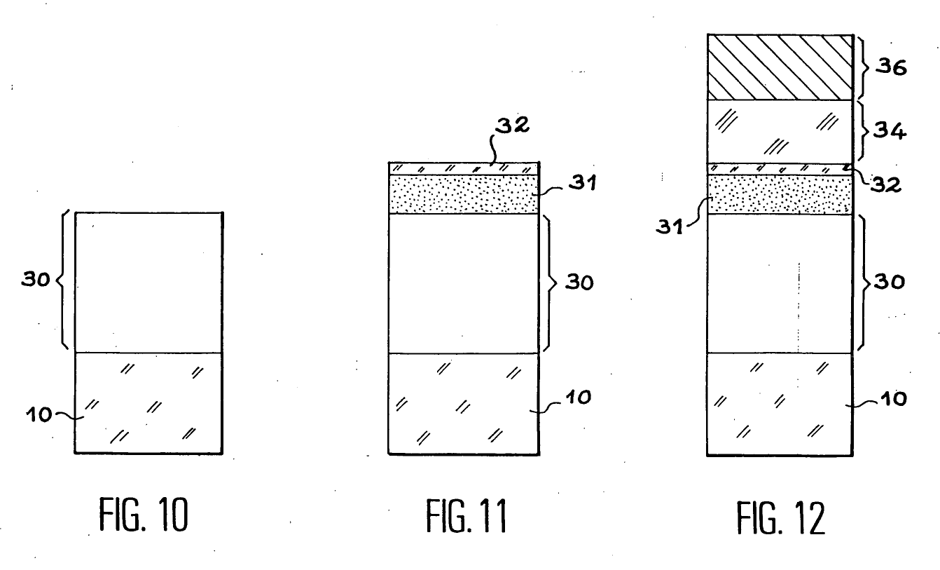

A second step illustrated by FIG. 11 comprises the formation of a layer of silicon oxide 31 and a layer of silicon 32 on the first mirror.

The silicon layer 32 is taken from a silicon block, on which it forms a surface layer. This block may possibly be covered by the oxide layer. The silicon layer, possibly covered by the oxide layer, is then transferred using the process described with reference to FIGS. 2 and 3.

The silicon oxide layer 31 may also be formed directly on the first mirror 30 and covered later by transferring the silicon layer 32.

However, the thickness of the transferred silicon layer 32 is not adjusted to a thickness corresponding to an optical thickness for the chosen wavelength.

In this case it is used as a support to promote subsequent growth of active materials to form an optical cavity. Thus the thickness of the silicon layer 32 is preferably very small. For example, its thickness may be between 5 and 200 nm.

FIG. 12 shows the growth of an active material to form an optical cavity 34 as described above.

It can be assumed that the silicon layer 32 forms part of the cavity 34, for the purposes of the calculation and adjusting the optical thickness of the cavity.

Finally, the cavity is covered by a second mirror 36 similar to the corresponding mirror in FIG. 9.

FIGS. 13 to 15 illustrate another possible application of the invention for the manufacture of an optical component.

FIGS. 13 and 14 show structures approximately identical to FIGS. 10 and 11 obtained using the same processes. Therefore, this document does not include a more detailed description of these structures.

However, it is found that the silicon layer 32 transferred to the first mirror 30 and covering the oxide layer 31 is much thicker than the layer in FIG. 11.

The silicon layer 32, the thickness of which is controlled by the depth of the cleavage area in the silicon block from which it originates, is chosen to be greater than the required optical thickness for the optical component.

The thickness of the silicon layer 32 is adjusted by polishing or etching to form an optical cavity.

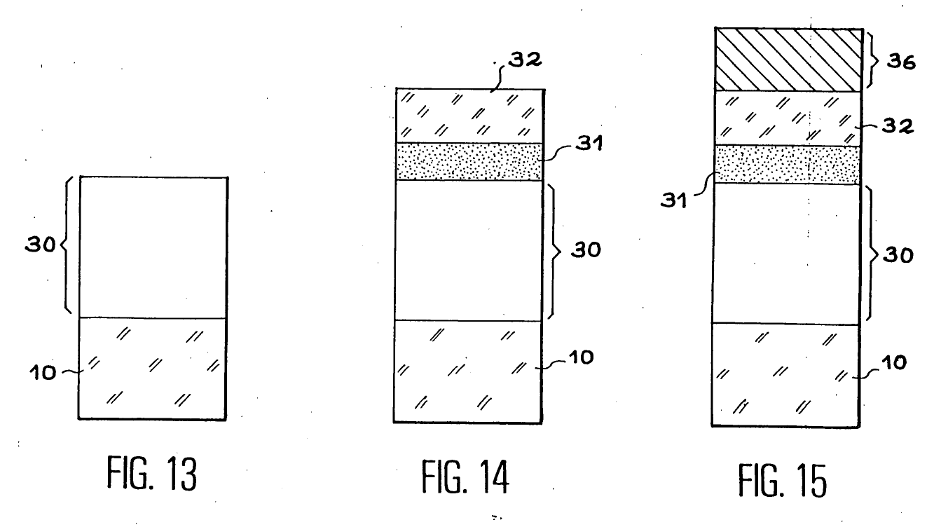

This cavity may be covered by a second mirror 36 as shown in FIG. 15.

The components referenced above may be associated with each other or with other optical or electronic components on the same substrate.

Similarly, when the optical cavities for components described are used as light emitters, they may be used with appropriate optical or electrical pumping means known in themselves.

### DOCUMENTS MENTIONED

References concerning documents mentioned in the text above, and documents providing technological background, are mentioned below.
(1)
“Epitaxy-ready Si/SiO2 Bragg reflectors by multiple separation-by-implanted-oxygen” Appl. Phys. Lett. 69(25), Dec. 16, 1996 by Yukari Ushikawa et al.
(2)
FR-A-2 681 472
(3)
“Giant enhancement of luminescence intensity in Er-doped Si/SiO2 resonant cavities” Appl. Phys. Lett. 61(12), Sep. 21, 1992 by E. F. Schubert et al.
(4)
“Silicon intersubband lasers” Superlattices and Microstructures, vol. 23, No. 2, 1998. By Richard A. Soref
(5)
“Prospects for novel Si-based optoelectronic devices: unipolar and p-i-p-i lasers” Thin Solid Films 294 (1997) 325-329 by Richard A. Soref
(6)
“Characterization of bond and etch-back silicon-on-insulator wafers by photoluminescence under ultraviolet excitation” Appl. Phys. Lett. 70(2), Jan. 13, 1977 By Michio Tajima et al.
(7)
“Luminescence due to electron-hole condensation in silicon-on-insulator” Journal of Applied Physics, Volume 84, No. 4, Aug. 15, 1998. by Michio Tajima et al.

What is claimed:

1. Process for the formation of a silicon layer (22a, 22b, 32, 34) for optical purposes with a determined (optical) thickness, on a support (10), characterized in that it comprises the following steps:
a) Molecular bonding of a silicon block (20a, 20b) on the support on which there may or may not already be other layers, the silicon block having a surface layer (22a, 22b, 32, 34) delimited by a cleavage area (21) substantially parallel to its surface, and with a thickness greater than or respectively less than the said determined thickness, and the silicon block being covered by a silicon oxide layer (12a, 12b) brought into contact with the support during bonding,
b) cleavage of the silicon block along the cleavage area to detach the surface layer fixed to the support from it,
c) thinning or respectively thickening the said surface layer until a thickness substantially equal to the said determined thickness, is obtained.

2. Process according to claim 1, in which the thickness of the surface layer (22a, 22b) of the silicon block used in step a) is greater than the determined thickness, and in which thinning of the surface layer in step c) comprises at least one oxidation operation followed by at least one etching operation and/or one polishing operation.

3. Process according to claim 1, in which the thickness of the surface layer (22a, 22b) of the silicon block (20a, 20b) used in step a) is less than the determined thickness, and the thickness of the surface layer is increased by crystalline growth during step c).

4. Process according to claim 1, in which a hydrogen implantation is performed before step a) through one of the faces (23) of the silicon block to form an embrittled area (21) in the block (20a, 20b), said embrittled area extending substantially along a plan parallel to the surface of said block and forming the cleavage area, the implantation energy being adjusted to form the cleavage area at a depth which is greater than or respectively less than the determined thickness.

5. Process for manufacturing a Bragg mirror with wavelength λ on a support, in which a stack of layers is formed comprising alternately at least one layer of silicon oxide (12a, 12b) with optical thickness
$$\frac{λ}{4 {n}_{o}} ,$$
where nₒ denotes the refraction index of the silicon oxide, and at least one silicon layer (22a, 22b) with an optical thickness equal to
$$\frac{λ}{4 {n}_{s}} ,$$
where nₛ is the refraction index of silicon, and in which the said silicon layer is formed according to the process mentioned in claim 1.

6. Process according to claim 5, in which the silicon oxide layer is formed by a chemical vapor deposition method or by thermal oxidation of silicon.

7. Process for manufacturing an optical component with a working wavelength λ comprising:
the formation of a Bragg mirror (30) according to the process described in claim 5,
formation of a layer of active material (34) on the Bragg mirror by crystalline growth, to form a cavity,
formation of a second mirror (36) on the cavity.

8. Process according to claim 7, in which the active material is chosen from among pure silicon, silicon containing one impurity, silicon carbide SiC and SiₓGe₁₋ₓ alloys where 0<x<1.

9. Process according to claim 7, comprising the formation of said second mirror by deposition of a metallic layer on the cavity.

10. Process according to claim 7, including the construction of the second mirror in the form of a Bragg mirror according to claim 5.

11. Process for manufacturing an optical component including the formation of a Bragg mirror on a support according to the process in claim 5, followed by the formation of an optical cavity by crystalline growth of at least one active material.

12. Process for the manufacture of an optical structure comprising:
formation of a first Bragg mirror (30) on a support,
formation of a silicon layer (32) on the Bragg mirror, according to the process according to claim 1, and
formation of a second mirror (36) above the silicon layer.

13. Process according to claim 12, in which the first and second mirrors are Bragg mirrors made according to the process in claim 5.

14. Process according to claim 12, in which the optical thickness of the silicon layer (32) is equal to
$$\frac{λ}{4 {n}_{s}} ,$$
where λ is the working wavelength of the optical structure and nₛ is the refraction index of the silicon.

15. Process according to claim 12, in which one or several layers (34) of active material chosen among SiGe, SiGeC and SiC are grown on the silicon layer before the formation of the second mirror, to form an optical cavity.
